(19) United States
(12) Patent Application Publication
(10) Pub. No.: US 2016/0260676 A1
(43) Pub. Date: Sep. 8, 2016

(54) SEMICONDUCTOR DEVICE HAVING GUARD METAL THAT SUPPRESS INVASION OF MOISTURE

(71) Applicant: SUMITOMO ELECTRIC DEVICE INNOVATIONS, INC., Yokohama-shi (JP)

(72) Inventor: Fumio YAMADA, Kofu-shi (JP)

(73) Assignee: SUMITOMO ELECTRIC DEVICE INNOVATIONS, INC., Yohohama-shi (JP)

(21) Appl. No.: 15/061,067

(22) Filed: Mar. 4, 2016

(30) Foreign Application Priority Data
Mar. 6, 2015 (JP) 2015-044350

(51) Int. Cl. H01L 23/00; H01L 29/205; H01L 29/778; H01L 29/20

(52) U.S. Cl. CPC H01L 23/564; H01L 29/2003; H01L 29/205; H01L 29/7787

(57) ABSTRACT

A semiconductor device having a structure to suppress invasion of moisture into a device area is disclosed. The semiconductor device provides the device area including structure for active operations and a peripheral area surrounding the device area and having no functions for the active operations. The semiconductor device further provides a guard metal that is in direct contact to the peripheral area and arranged between a drain pad and a source electrode of the semiconductor device. The guard metal may suppress moisture invading from an opening in the drain pad into the device area.

### BACKGROUND OF THE INVENTION

1. Field of the Invention

The present invention relates to a semiconductor device, in particular, the invention relates to a semiconductor device having a mechanism to suppress invasion of moisture into a device area.

2. Related Background Arts

FIG. 20 shows a cross section around a pad 104 on an insulating film 104 provided in a semiconductor device 100. Another insulating film 106 partially covers the pad 104; specifically, the insulating film 106 only covers peripheries of the pad 103 so as to leave an opening 106a therein. The bonding wire 108 is in contact to the pad 103 as filling the opening 106a of the insulating film 106. This arrangement shown in FIG. 20 may suppress moisture from invading into the interface between the insulating film 106 and the pad 104 by the bonding wire 108 filling the opening 106a.

An ordinary semiconductor device such as a filed effect transistor (FET) usually provides a drain pad and a source pad to electrically connect the FET to other devices and/or electrical components, where those pads are covered with an insulating film as leaving an opening on the pads in order to connect bonding wires thereto, When such an FET is encapsulated by a resin package, moisture easily invades within the resin package and reaches the PET. The invading moisture further invades into the FET through the opening formed in the insulating film and along the interface between the insulating film and the semiconductor material, and finally reaches the active area of the FET. The moisture accelerates the electromigration of the electrodes, and possibly causes short circuits between electrodes. As the bias applied to the electrodes becomes higher, the electromigration is accelerated. When the semiconductor device is primarily made of nitride semiconductor materials, typically, gallium nitride (GaN), the electromigration of the electrodes has become an important subject because GaN-FETs may operate by higher biases. Accordingly, a semiconductor device primarily made of nitride semiconductor materials is necessary to have enough moisture resistance.

### SUMMARY OF THE INVENTION

An aspect of the present invention relates to a semiconductor device that includes a semiconductor layer, a gate electrode, a drain electrode and a source electrode, a pad, an insulating film, and the guard metal. The semiconductor layer includes a device area and a peripheral area surrounding the device area. The device area has active functions of the semiconductor device. The peripheral area has no active functions. The gate electrode is provided on the device area. The drain electrode and the source electrode, where they are also provided on the device area sandwiches the gate electrode therebetween. The pad is provided on the peripheral area and connected to one of the drain electrode and the source electrode. The insulating film covers the pad but has an opening on the pad so as to expose the pad, The guard metal is provided between the pad and the other of the source electrode and the drain electrode not connected to the pad. The guard metal is in direct contact to semiconductor layer in the peripheral area.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a plan view of a semiconductor device according to the first embodiment of the present application;

FIG. 2 shows a cross section of the semiconductor device taken along the line II-II indicated in FIG. 1;

FIG. 3 shows a cross section of the semiconductor device taken along the line III-III indicated in FIG. 1;

FIG. 4 shows a cross section of the semiconductor device taken along the line IV-IV indicated in FIG. 1;

FIGS. 5A to 5F show processes of forming the guard metal;

FIG. 6 is a plan view of another semiconductor device with no guard metal;

FIG. 7 shows paths that moisture invades into the device area from the opening in the insulating film covering the pad;

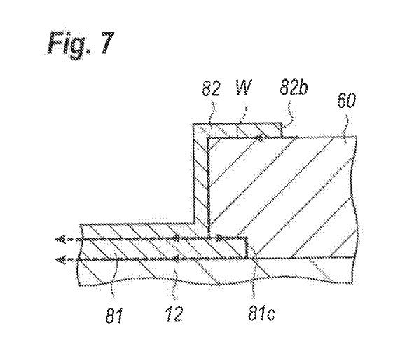

FIG. 8 shows a function of the guard metal of the present invention which makes moisture to be hard to invade into the device area;

FIG. 9 is a plan view of a semiconductor device according to the first modification from the semiconductor device shown in FIG. 1;

FIG. 10 is a plan view of a semiconductor device according to the second modification from the semiconductor device shown in FIG. 1;

FIG. 11 shows a cross section of the semiconductor device taken along the line XI-XI appearing in FIG. 10;

FIG. 12 shows a cross section of the semiconductor device taken along the ling XII-XII indicated in FIG. 10;

FIG. 13 is a plan view showing a semiconductor device according to the third modification from the semiconductor device shown in FIG. 1;

FIG. 14 is a plan view showing a semiconductor device according to the fourth modification of the semiconductor device shown in FIG. 1;

FIG. 15 shows a cross section around the guard metal according to the fifth modification of the semiconductor device shown in FIG. 1;

FIG. 15 shows a cross section around the guard metal according to the sixth modification of the semiconductor device shown in FIG. 1;

FIG. 17 is a plan view showing a semiconductor device according to the seventh modification of the semiconductor device shown in FIG. 1;

FIG. 18 shows a cross section around the guard metal shown in FIG. 17;

FIG. 19 is a plan view of a semiconductor device according to the eighth modification of the semiconductor device shown in FIG. 1; and

FIG. 20 shows a cross section around a pad in a conventional arrangement.

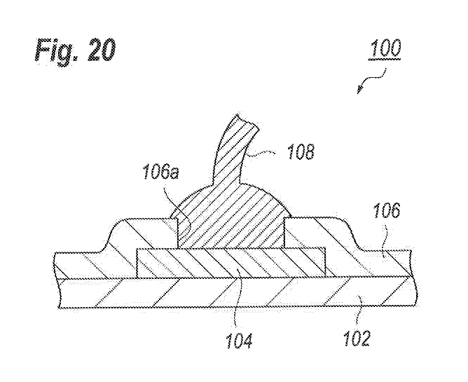

### DESCRIPTION OF EMBODIMENT

Next, some examples according to the present application will be described as referring to accompanying drawings. The present invention is not restricted to those examples, and has scopes indicated by claims and all equivalents thereof. In the description below, numerals or symbols same with or similar to each other will refer to elements same with or similar to each other without duplicating explanations.

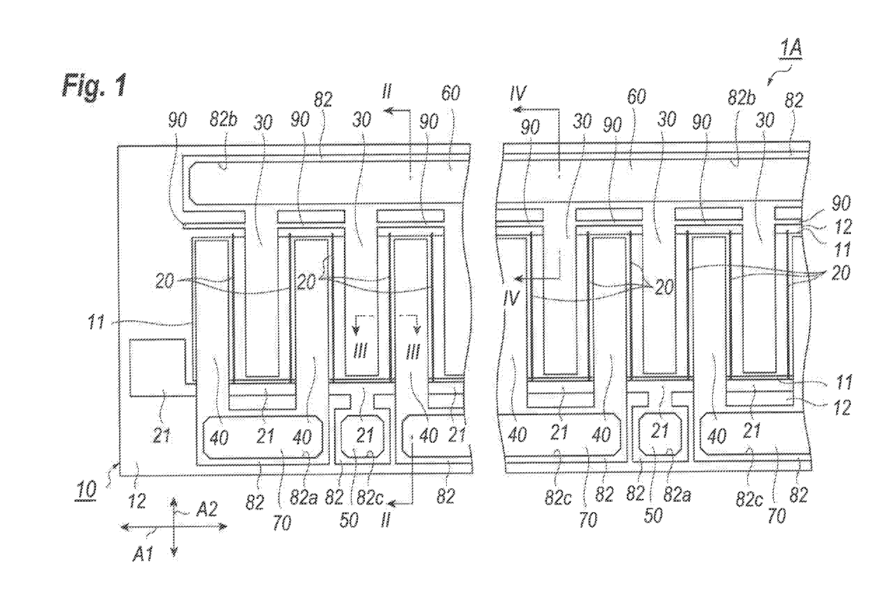

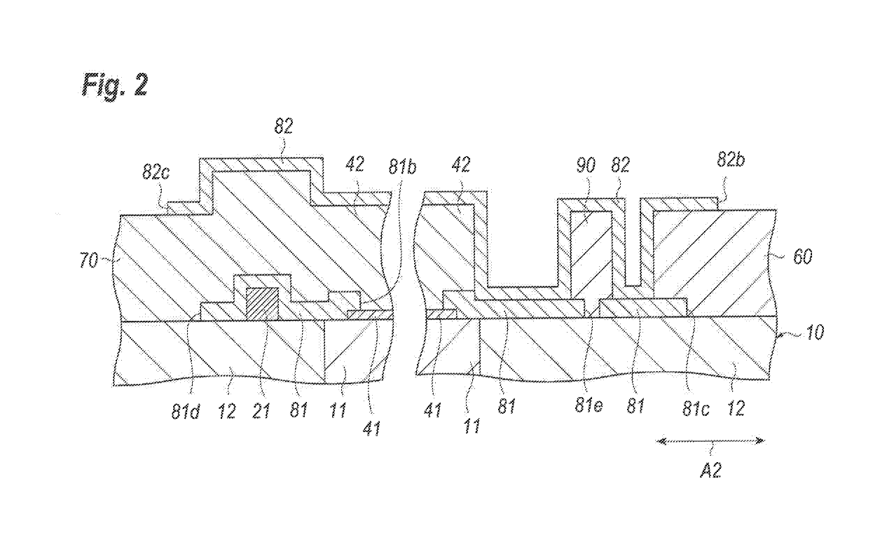

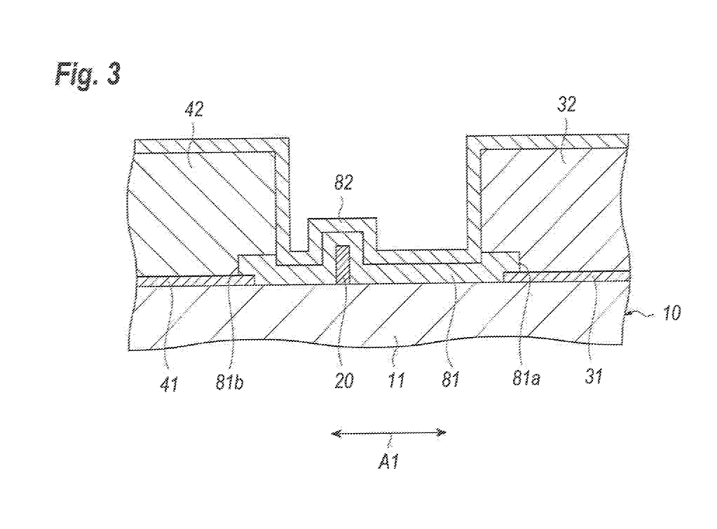

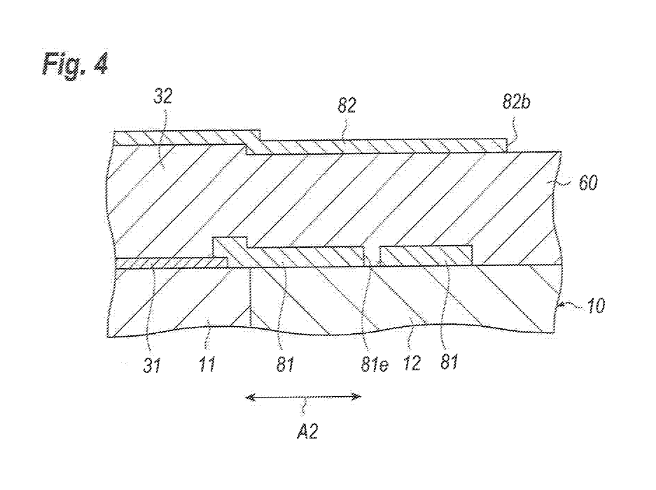

FIG. 1 is a plan view of a semiconductor device 1A according to an example of the present invention, FIG. 2 shows a cross section of the semiconductor device 1A taken along the line II-II, FIG. 3 also shows a cross section taken along the line III-III, and FIG. 4 also shows a cross section of the semiconductor device taken along the line IV-IV, each appearing in FIG. 1. The semiconductor device 1A includes a semiconductor layer 10, a plurality of gate electrodes 20, a plurality of drain electrodes 30, a plurality of source electrodes 40, a gate pad 50, a drain pad 60, a source pad 70, insulating films, 81 and 82, and guard metals 90.

The semiconductor layer 10 may be primarily made of III-V compound semiconductor materials involved in gallium nitride (GaN) group and/or gallium arsenide (GaAs) group. Examples of the semiconductor layer 10 are the semiconductor materials in the GaN group epitaxially grown on a silicon carbide (SiC) substrate, or the semiconductor materials in the GaAs group also epitaxially grown on a GaAs substrate. The semiconductor layer 10 includes a device area 11 and a peripheral area 12 surrounding the device area 11. The device area 11 has structure of, for instance, a field effect transistor (FET) formed in a surface regions and extending along a direction A1. The device area 11 provides a drain region and a source region each having a first conduction type, typically the n-conduction type, where the former region is in contact to the drain electrode 30, while, the latter region is in contact to the source electrode 40. The device area 11 further provides a channel region that is in contact to the gate electrode 20. The peripheral area 12 electrically isolates the device area 11 from other device areas also provided on the semiconductor substrate. The peripheral area 12 may be formed by the ion implantation of argon (Ar) ions, which increases the resistivity therein, or by etching so as to form a mesa including the device area 11. The semiconductor layer 10 may further include a carrier-supplying layer on the channel layer and a cap layer on the carrier-supplying layer. When the semiconductor materials of the semiconductor layer 10 are the GaN group, the carrier-supplying layer may be made of AlGaN layer, and the cap layer may be made of GaN layer. In this arrangement of the semiconductor layer 10, the AlGaN layer induces carriers, namely electrons, within an interface against the channel layer therebeneath caused by the lattice mismatching of the AlGaN layer with respect to the channel layer.

The gate electrodes 20, which are made of metal films, are fully covered with the insulating film 82. Each of the gate electrodes 20 extends along the direction A2 and has a large aspect ratio, that is, a lengthened longitudinal length with a narrowed lateral width. The gate electrodes 20 each crosses the device area 11 along the direction A2 and has an end connected to the gate bar 21 that extends along the direction A1. The gate bar 21 is also covered with the insulating film 82.

The gate pads 50, which provided in the peripheral area 12 and adjacent to the gate bar 21, are metal films. The gate pads 50 are also covered with the insulating film 82 as leaving respective center portions. That is, the insulating film 82 has openings 82a each exposing center portions of the gate pads 50 so as to enable the wire-bonding thereto.

The drain electrodes 30 are metal films each formed in the drain regions in the device area 11. The drain electrodes 30 each includes the drain contact 31 in contact to the drain region and a metal film 32 provided on the drain contact 31. The drain contact 31, which is what is called an ohmic contact, may be made of titanium. (Ti), while, the metal film 32 is made of gold (Au). In the semiconductor device 1A, the drain contact is in contact to the cap layer, namely, the surface of the semiconductor layer 10 as illustrated in FIG. 3, but the drain contact may be in contact to the carrier-supplying layer under the cap layer.

The drain electrodes 30 are fully covered with the insulating film 82. As illustrated in FIG. 1, the drain electrodes 30 has a lengthened rectangular plane shape extending along the direction A2 so as to cross the device area 11. The drain electrodes 30, each arranged in parallel along the direction A1, are connected in respective ends thereof to the drain pad 60 which is a metal film. Specifically, the drain pad 60, which is arranged on the peripheral area 12 in a side opposite to the gate pad 50 with respect to the device area 11, extends along the direction A1. The drain pad 60 is covered with the insulating film 82 except for central regions thereof That is, the insulating film 82 provides an opening 82b in the central regions of the drain pad 60 to enable the wire-bonding to the drain pad 60 exposed from the opening 82b.

The source electrodes 40, which are metal films formed in the source regions, each includes a source contact 41 in contact to the source region and a metal film 42 provided on the source contact 41. The source contact 41 may be also titanium (Ti), while, the metal film 42 is made of gold (Au). In FIG. 4, the source contact 41 is in contact to the cap layer, namely, the surface of the semiconductor layer 10, the source contact 41 may be in contact to the carrier-supplying layer beneath the cap layer by partially removing the cap layer.

The source electrodes 40, which are also covered with the insulating film 82, each has a lengthened rectangle extending along the direction A2 so as to traverse the device area 11. The source electrodes 40 are arranged, along the direction A1, in a side opposite to the drain electrodes 30 with respect to the gate electrode 20; that is, the source electrode 40 and the drain electrode 30 put the gate electrode 20 therebetween. The semiconductor device 1A of the present invention iterates those electrodes, 20 to 40, by a pattern of the drain electrode 30, the gate electrode 20, the source electrode 40, the gate electrode 20, the drain electrode 30, and so on.

The source electrodes 40 in respective ends thereof are connected to the source pad 70 that extend along the direction A1. The source pad 70 may be a metal film provided on the peripheral area 12 in a side. where the gate pad 50 is formed. The source pad 70 may be in directly contact to the semiconductor layer 10 in the peripheral area 12. The source pad 70 except for center portions thereof may be covered also with the insulating film 82; that is, the insulating film 82 has an opening on the source pad 70 through which the wire-bonding to the source pad 70 may be carried out.

The guard metals 90, which extend along the direction A1 from the gate electrode 20 between the gate pad 50 and the source electrodes 40, are in contact to the semiconductor layer 10 in the peripheral area 12. That is, the guard metals 90 electrically connect the gate electrodes 20 adjacent to each other in the side between the source electrodes 40 and the gate pad 50. The guard metals 90 of the present embodiment, which is formed concurrently with the gate electrode 20, may be made of material same with that of the drain electrode 30. Thus, the guard metals 90 are electrically connected to the drain pad 60. The guard metals 90 each have a width of 1 to 50 μm. The guard metals 90 may be effective for prevent moisture from invading to the device area 11 from regions between the source electrodes 40 and the gate pad 50.

The insulating film 81 covers the semiconductor layer 10 and in contact thereto. As illustrated in FIGS. 2 and 3, the insulating film 81 provides the opening 81a to connect the metal film 32 to the drain contact 31 and another opening Sib to connect the metal film 42 to the source contact 41. The gate electrode 20 is in direct contact, namely, the Schottky contact, to the surface of the semiconductor layer 10 and fully covered with the insulating film 81. The insulating film 81 provides the opening 81c for the drain pad 60 to be in contact to the semiconductor layer 10 in the peripheral area 12, another opening 81d for the source pad 70 to be in contact to the semiconductor layer 10 in the peripheral area 12, and the opening 81e for the guard metal to be in contact to the semiconductor layer 10 in the peripheral area 12. The insulating film 81 may have a thickness of about 500 nm.

The other insulating film 82 is provided on the insulating film 81 and has a function of a passivation film The insulating film 82, as already described, covers the gate electrode 20, the drain electrode 30, the source electrode 40, the gate pad 50, the drain pad 60, the source pad 70, and the guard metal 90. Those insulating films, 81 and 92, may be made of silicon compound such as silicon nitride (SiN), silicon oxide (SiO₂), silicon oxi-nitride (SiON), and so on. The second insulating film 82 may have a thickness of, for instance 500 nm. Thus, the guard metal 90, which is in direct contact to the semiconductor layer 10 in the peripheral area 12, may suppress moisture from invading into the device area 11.

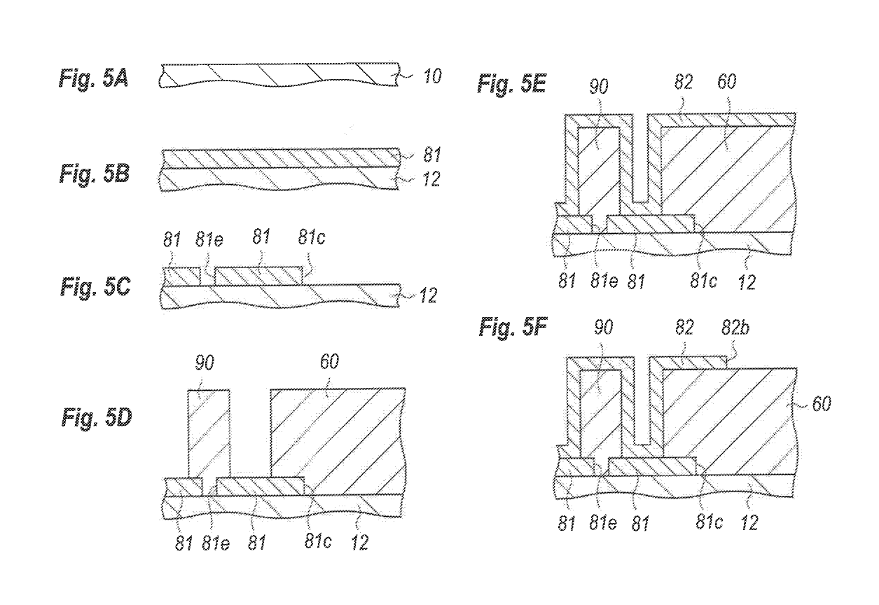

Next, a process of forming the semiconductor device 1A will be described. The description concentrates on the processes to form the drain pad 60, the guard metal 90, and arrangements around the drain 60 and the guard metal 90 as referring to FIGS. 5A to 5F. The process first prepares the semiconductor layer 10 (FIG. 5A); then, forms the device area 11 within the semiconductor layer 10. Concurrently with the formation of the device area 11, the process forms the insulating film 81 on the surface of the semiconductor layer 10, as shown in FIG. 5B.

A conventional lithography technique with subsequent etching using chloride (Cl) as a reaction gas may form the openings, 81c and 81e, in the insulating film 81, as shown in FIG. 5C. Depositing seed metals of titanium and gold (Ti/Au) on the semiconductor layer 10 within the openings, Sic and 81e, by thicknesses of 10 and 100 nm, respectively, and subsequent plating gold (Au) by a thickness of for instance, 4 μm; the drain pad 60 and the guard metal 90 may be formed on the semiconductor layer 10, FIG. 5D, Subsequently, the second insulating film 82 covers the drain pad 60, the guard metal 90, and portions of the insulating film 81 exposed from the drain pad 60 and the guard metal 90, FIG. 5E. Lastly, a conventional photo-lithography and a subsequent etching of the second insulating film 82 by using a chloride (Cl) gas may form the opening 82b in the second insulating film 82. Thus, structures around the drain pad 60 and the guard metal 90 may be formed.

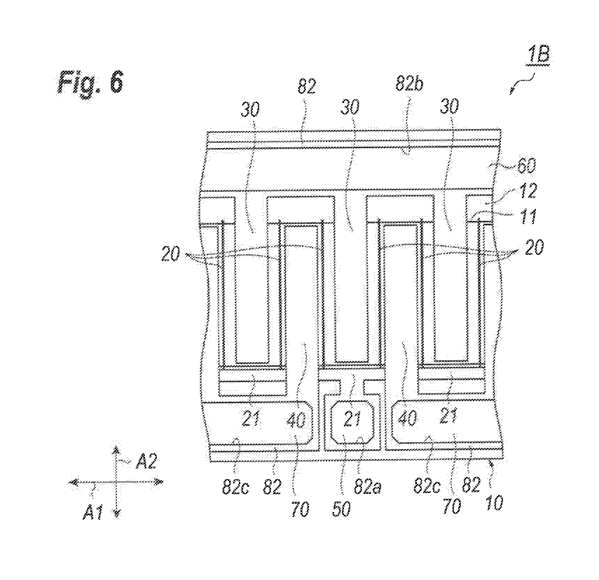

Advantages of the semiconductor device thus configured will be next described. FIG. 6 is a plan view of a semiconductor device 1B comparable to the semiconductor device 1A of the embodiment, where the comparable device 1B does not have guard metals 90. When moisture W invades into an interface between the drain pad 60 and the insulating film 82, which is exposed from the opening 82b of the insulating film 82, the moisture W penetrates into the device area 11 along the interface between the insulating film 82 and the other insulating film 81, and between the insulating film 81 and the peripheral area 12. The moisture W invading into the device area 11 finally induces the electromigration, which is the corrosion caused by the moisture accelerated by an electric field. The moisture W invading into the device area 11 ionizes metals of the electrodes by the electric field applied between the drain electrode 30 and the gate electrode 20, or between the drain electrode 30 and the source electrode 40. Positive ions are moved toward the negative electrode, while, negative ions are pulled toward the positive electrode, which generates leak current between the electrodes and degrades the device performance of the FET. Further electromigration makes the electrodes closer to each other because of the extraction of the ionized metal ions and the deposition of the extracted metal ions, which elongates the electrodes. Applying biases between the electrodes excessively closer to each other, the dielectric breakdown occurs between the electrodes, which possibly makes the drain electrode 30 or the source electrode 40 in short circuit to the gate electrode 20.

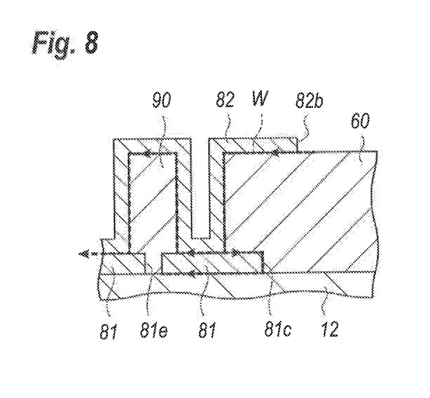

The semiconductor device 1A of the present embodiment, as shown in FIG. 8, provides the guard metal 90 between the source electrode 40 and the drain pad 60, and the guard metal 90 is in direct contact to the surface of the semiconductor layer 10 in the peripheral area 12. An interface between a metal and a semiconductor shows an effective barrier for the invasion of moisture compared with an interface between an insulating film and another insulating film, or between a metal and an insulating film. Accordingly, invading moisture W may be effectively suppressed to further invade into the device area 11 by the interface between the guard metal 90 and the semiconductor layer 10 in the peripheral area 12. Moisture W invading into the device area 11 further invades along the interface between the insulating film 82 and another insulating film 81. However, the moisture W is necessary to get over the guard metal 90 during the invasion, which elongates a path for the moisture W invading into the device area 11 compared with a case where no guard metal exists, Thus, the guard metal 90 preferably has a substantial thickness as possible. Because the drain pad 60 has a substantial thickness to release mechanical pressure during the wire boding, the guard metal 90 is preferably formed concurrently with the formation of the drain pad 60.

Thus, the semiconductor device 1A of the present embodiment may effectively suppress or prevent the moisture W from invading into the device area 11, which may effectively enhance the moisture resistance of the semiconductor device 1A. Thus, the guard metal 90 formed between the drain pad 60 and the source electrode 40 may enhance the long-term reliability of the semiconductor device 1A. A semiconductor device is often biased in largest between the drain electrode and the source electrode, that is, the drain electrode is most likely to cause the electromigration. Accordingly, the guard metal 90 formed between the drain pad 60 and the source electrode 40 becomes effective for the moisture resistance of the semiconductor device.

The description thus presented concentrates on the semiconductor device primarily made of nitride semiconductor materials such as GaN. However, the arrangement of the guard metal 90 may be applicable to semiconductor devices made of GaAs and semiconductor materials grouped in GaAs. Because semiconductor devices of the GaN group and the GaAs group are often operated under high biases, such semiconductor devices easily cause the electromigration. The guard metal 90 of the present embodiment may suppress the electromigration and enhance the moisture resistance of the device.

First Modification

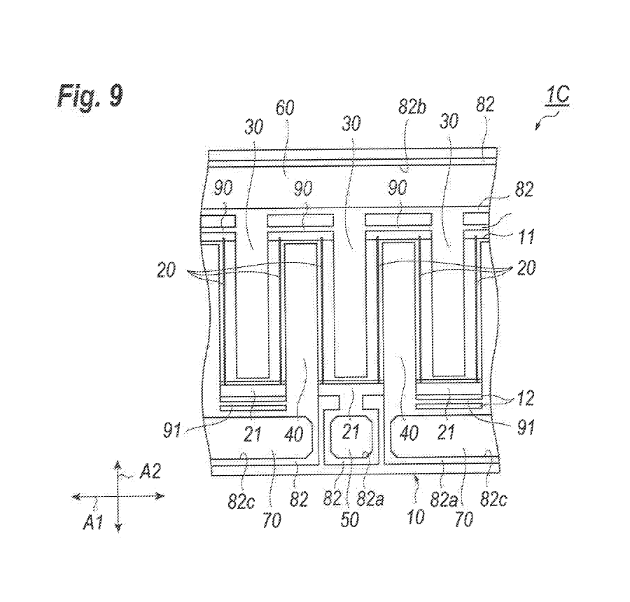

FIG. 9 is a plan view of a semiconductor device 1C according to the first modification of the aforementioned embodiment. The semiconductor device 1C provides, in addition to the guard metal 90, another guard metal 91 provided on the peripheral area 12 in the side of the source pad 70. The other guard metal 91, which is in direct contact to the semiconductor layer 10, connects the source electrodes 40 adjacent to each other. The other guard metal 91, which has a lengthened rectangular shape extending along the direction A1, may be made of material same with that of the source electrode 40 and the source pad 70. Accordingly, the other guard metal 91 may be preferably formed concurrently with the source electrode 40 and the source pad 70.

The moisture W invades from not only the drain pad 60 but from the source pad 70. The other guard metal 91 provided between the source pad 70 and the device area 11 may effectively suppress the invasion of the moisture into the device area 11 under the gate electrode 20 and the drain electrode 30. A semiconductor device may provide only one of the guard metals, 90 and 91, or both of the guard metals, 90 and 91. When the semiconductor device provides only the guard metal 91, the source electrode 40 operates as the primary electrode, while, the drain electrode 30 plays a role of the subsidiary electrode.

Second Modification

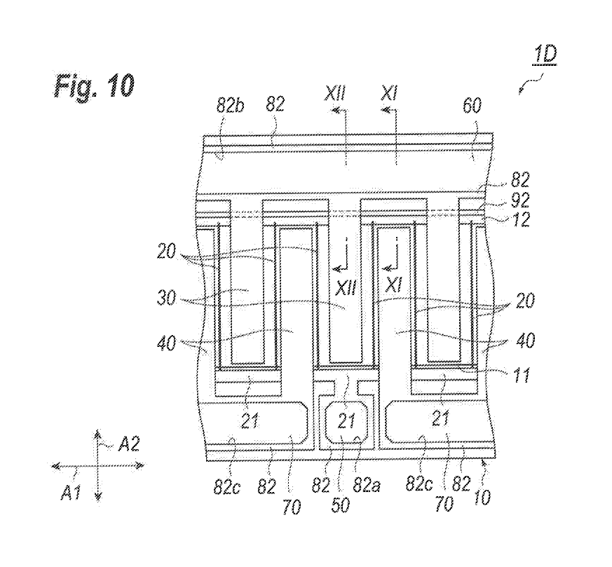

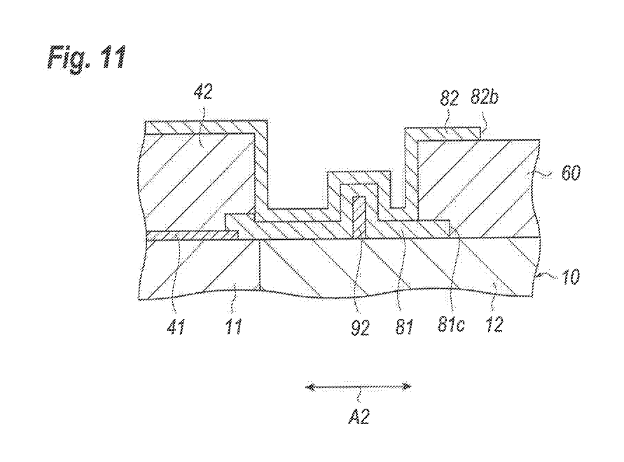

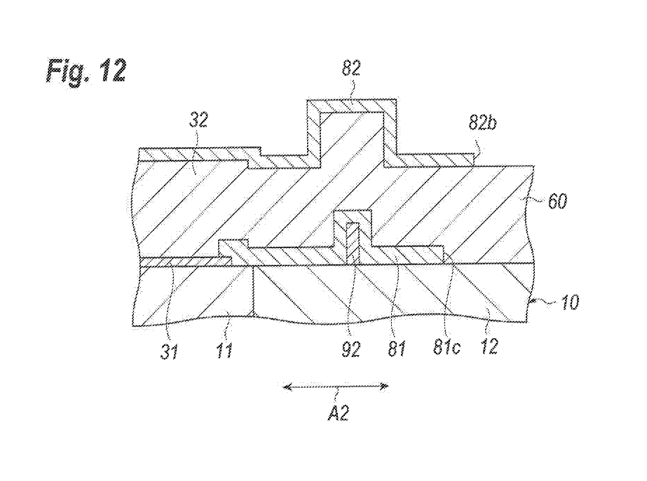

FIG. 10 is a plan view of a semiconductor device 1D according to the second modification of the aforementioned device 1A, FIG. 11 shows a cross section of the semiconductor device 1D taken along the line XI-XI, and FIG. 12 also shows a cross section of the semiconductor device 1D taken along the line XII-XII, both of which are indicated in FIG. 10. The semiconductor device 1D of the present modification has a feature of the guard metal, in particular, arrangements of the guard metal. Other arrangements except for the guard metal are substantially same with those of the aforementioned embodiment.

The guard metal 92 of the present modification is formed so as to be in contact to the semiconductor layer 10 of the peripheral area 12 in the side of the drain pad 60, specifically, the guard metal 92 is provided between the drain pad 60 and the source electrode 40. As illustrated in FIGS. 10 to 12, the guard metal 92 is not connected to the drain pad 60 different from the guard metal 90, That is, the guard metal 92 of the present modification is preferably formed concurrently with the gate electrode 20, and has a metal stack of nickel (Ni) and gold (Au). In an example, Ni has a thickness of 50 nm, while, Au has a thickness of 500 nm. When the guard metal 92 is concurrently formed with the gate electrode 20, the metal evaporation may form those guard metal 92. The guard metal 92 may be formed independent of the gate electrode 20.

The insulating film 81 exists between the drain electrode 30 and the guard metal 92; that is, the insulating film 81 fully covers the guard metal 92. In the present modification, the insulating film 81 has no openings 81e, which means that the process of forming the guard metal 92 first forms the guard metal 92 then fully covers the guard metal 92 with the insulating film 81.

The guard metal 92 of the present modification may show functions same with those of the guard metals, 90 and 91. Also, the guard metal 92 of the present modification is independent of the drain pad 60, that is, the guard metal 92 is made of materials different from those of the drain pad 60, which means that the guard metal 92 may be made of materials suitable only for the function attributed to the guard metal 92, for instance, materials having superior adhesion to the semiconductor layer 10 may be selected for the guard metal without taking electrical characteristics thereof into account, Also, the guard metal 92 is electrically isolated from the gate metal 92 and the drain electrode 30 by the insulating film 81 in the stacking direction, namely, the vertical direction thereof, which means that the guard metal 92 of the present modification may show substantially no contribution to parasitic capacitance around the gate electrode 20 and the drain electrode 30.

Third Modification

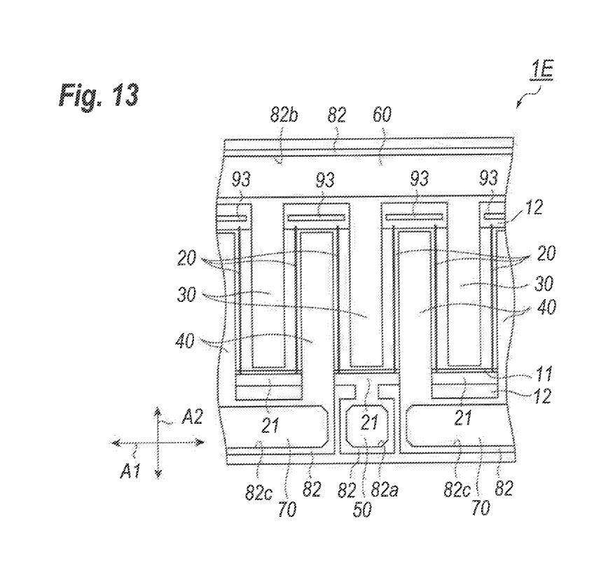

FIG. 13 is a plan view showing semiconductor device 1E according to the third modification of the present invention. The semiconductor device 1E has a feature distinguishable from the aforementioned devices in that the guard metal 93 of the present modification discretely distributes in respective source electrode 40. That is, as illustrated in FIG. 13, the guard metal 93 of the present modification are divided into parts each discretely disposed between the ends of the source electrodes 40 and the drain pad 60 in the peripheral area 12. The guard metals 93 each extends along the direction A1 but independent to each other. The guard metals 93 of the present modification may show functions same with those of the aforementioned guard metal 92. That is, because the guard metals 93 are electrically isolated from the gate electrode 20, the source electrode 40, and the drain pad 60, the guard metal 93 show no contribution to increase parasitic capacitance of the semiconductor device 1E. Also, the guard metals 93 may be made of materials independent of those of the gate electrode 20, the drain electrode 30, the source electrode 40, and respective pads, 50 to 70.

Fourth Modification

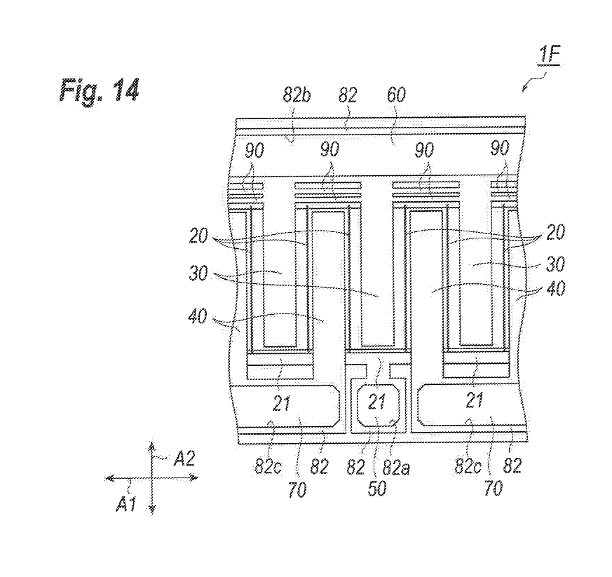

FIG. 14 is a plan view of still another modification of the semiconductor device 1F. The semiconductor device 1F has a feature distinguishable from the aforementioned semiconductor devices, 1A to 1E, in that the number of the guard metal 90 provided between the source electrode 40 and drain pad 60 is not one, that is, a plurality of guard metals 90 each extending in parallel along the direction A1 is formed on the semiconductor layer 10 in the peripheral area 12. FIG. 14 illustrates two guard metals 90 running in parallel between the source electrode 40 and the drain pad 60. Two or more guard metals may enhance the function to suppress the invasion of the moisture into the device area 11.

Fifth Modification

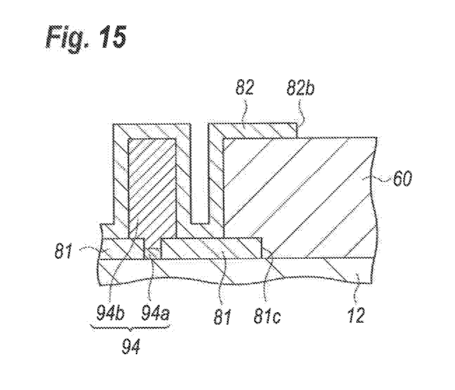

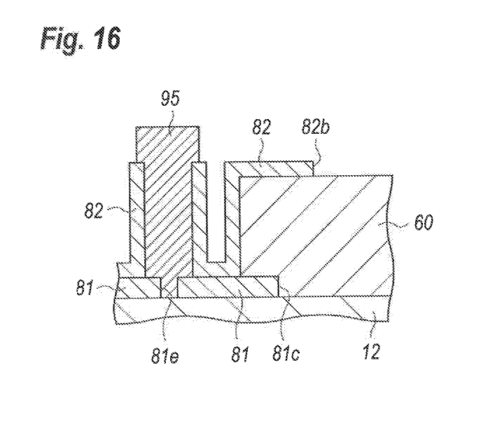

FIG. 15 shows cross sections of the guard metal 94 according to the fifth modification of the guard metal. The guard metal 94 of the present modification includes a first metal 94a in direct contact to semiconductor layer 10 in the peripheral area and a second metal 94b provided on the first metal 94a. These metals, 94a and 94b, are made of materials different from others. One example of the first metal 94a is made of titanium (Ti) or alloy containing Ti, while, the second metal 94b is made of gold (Au) or alloy containing Au. Thus, the guard metal 94 of the present modification may select a metal with superior adhesion to the semiconductor layer 10 for the first metal 94a and another metal for securing enough thickness for the guard metal 94 may be selected for the second metal 94b. One example shown in FIG. 15 provides the first metal 94a with a thickness of 100 nm formed by the sputtering, and the second metal 94b formed by the plating, where the plating is suitable technique to deposit a metal with enough thickness.

Sixth Modification

FIG. 16 shows a cross section of the guard metal 95 according to still another modification of the present invention. The guard metal 95 of the present modification has a feature that a top thereof exposes from the insulating film 82. The moisture W invading along the interface between the guard metal 95 and the insulating film 81 is prohibited in the invasion thereof at portions of the guard metal 95 exposed from the insulating film 82. Moisture possibly invading from the exposed portions of the guard metal 95 may be substantially out of consideration because of the exposed area of the guard metal 95 is far smaller than that of the drain pad 60, namely, the opening 82b of the insulating film 82 on the drain pad 60. The guard metal 95 may be made of materials same with those of the drain electrode 30 and/or the drain pad 60; but the guard metal 95 may be not restricted to those materials.

Seventh Modification

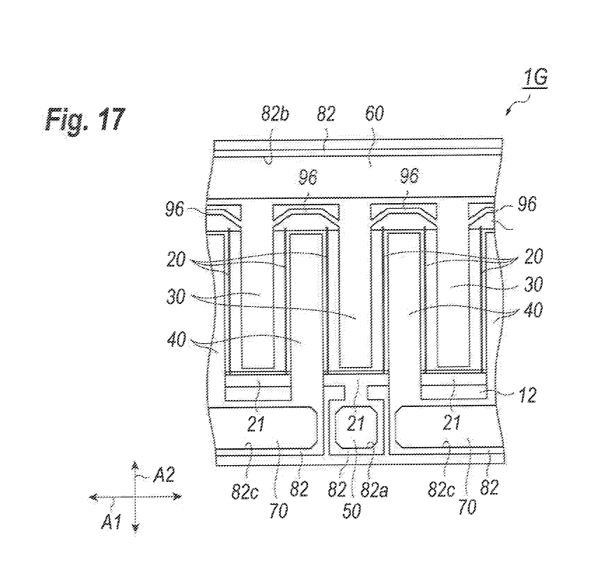

FIG. 17 is a plan view of the semiconductor device 1G having a guard metal according to still another modification of the present invention. The semiconductor device 1G has a feature distinguishable from those aforementioned examples in that the guard metal 96 shapes a polygonal line, that is, respective ends of the guard metal 96 make substantial angles with respect to the axis A1. Thus, the guard metal 96 is not restricted to a linear shape extending along the line A1, and may have various shapes.

Eighth Modification

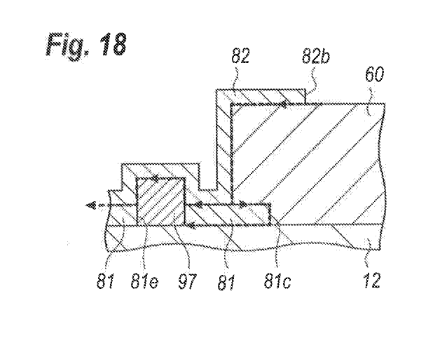

FIG. 18 shows a cross section around the guard metal 97 according to the eighth modification of the present invention. The guard metal 97 shown in FIG. 18 has a feature that a thickness thereof is smaller than those of the aforementioned guard rings, 90 to 96. That is, the guard metals, 90 to 97, according to the present invention are independent of thicknesses thereof for showing functions anticipated to the guard metals, 90 to 97. The guard metal 97 of the present modification may be also formed concurrently with the drain electrode 30 and/or the drain pad 60, but the guard metal 97 may be formed independent of the drain electrode 30 and the drain pad 60.

Ninth Modification

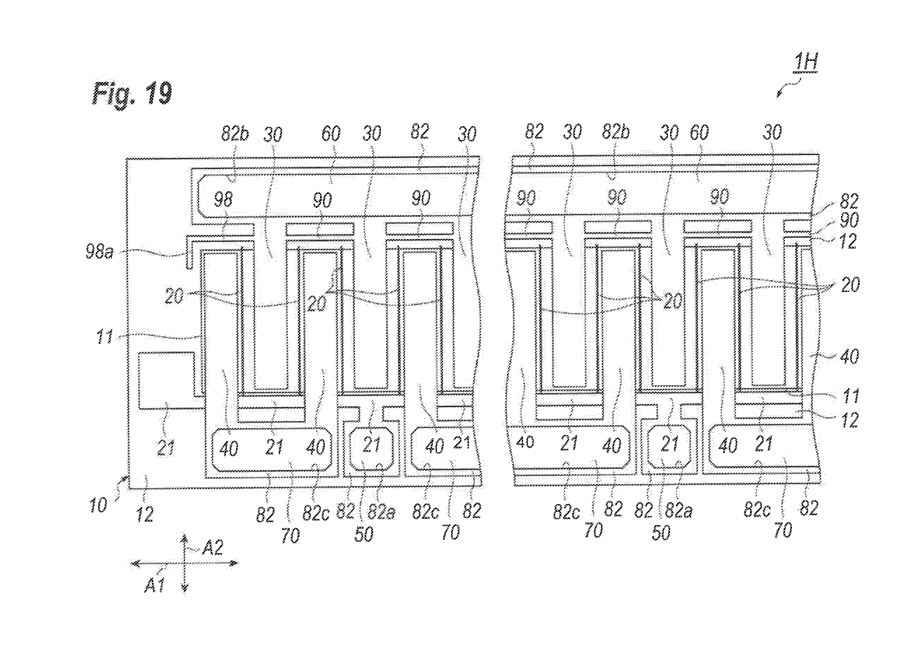

FIG. 19 is a plan view of a semiconductor device 1H according to the ninth modification of the present invention. The semiconductor device 1H has a feature that the guard metal 90 has a plane shape thereof distinguishable from that of the aforementioned guard metals, 90 to 97. That is, the guard metal 98 in the outermost part thereof provides an extension 98a bent from the primary portion 98 thereof and extending along the source electrode 40. The extension 98a of the guard metal 98 may effectively suppress the moisture from invading into the device area 11 from the side of the source electrode 40.

While particular examples of the present invention have been described herein for purposes of illustration, further modifications and changes will become apparent to those skilled in the art. For instance, the embodiment and the modifications thus described concentrate on a case where the semiconductor layer 10 is made of group III-V compound semiconductor materials. However, the functions and the arrangements of the present invention may be applicable to cases where the semiconductor layer 10 is made of intrinsic semiconductor materials. Accordingly, the appended claims are intended to encompass all such modifications and changes as fall within the true spirit and scope of this invention.

I claim:

1. A semiconductor device, comprising:
a semiconductor layer including a device area and a peripheral area surrounding the device area, the device area having active functions of the semiconductor device and the peripheral area having no active function;
a gate electrode provided on the active area;
a drain electrode and a source electrode provided on the active area and sandwiching the gate electrode therebetween;
a pad provided on the peripheral area, the pad being connected to one of the drain electrode and the source electrode:
an insulating film covering the pad and having an opening on the pad; and
a guard metal provided between the pad and another of the drain electrode and the source electrode, the guard metal being in direct contact to the semiconductor layer in the peripheral area.

2. The semiconductor device of claim 1,
wherein the guard metal is covered with the insulating film.

3. The semiconductor device of claim 2,
wherein the guard metal in a top portion thereof exposes from the insulating film.

4. The semiconductor device of claim 1,
wherein the pad is connected to the drain electrode and the guard metal is provided between the drain pad and the source electrode.

5. The semiconductor device of claim
wherein the pad is connected to the source electrode and the guard metal is provided between the source pad and the drain electrode.

6. The semiconductor device of claim 5,
further providing another guard metal provided between the drain pad and the source electrode.

7. The semiconductor device of claim 1,
wherein the guard metal is divided into a plural portions each extending in parallel.

8. The semiconductor device of claim 1,
wherein the guard metal is electrically connected to the pad.

9. The semiconductor device of claim 1,
wherein the guard metal is electrically isolated from the gate electrode, the source electrode, and the drain electrode.

10. The semiconductor device of claim 1,
wherein the guard metal includes a first metal in direct contact to the peripheral area and a second metal provide on the first metal.
